(19) United States
(12) Patent Application Publication
(10) Pub. No.: US 2020/0384884 A1
(43) Pub. Date: Dec. 10, 2020

(54) BATTERY STATE DETERMINING SYSTEM, IN-VEHICLE DEVICE, SERVER, BATTERY STATE DETERMINING METHOD, AND PROGRAM

(71) Applicant: HONDA MOTOR CO., LTD., Tokyo (JP)

(72) Inventor: Shigeru Namiki, Wako-shi (JP)

(21) Appl. No.: 16/871,091

(22) Filed: May 11, 2020

(30) Foreign Application Priority Data
May 23, 2019 (JP) 2019-097060

(51) Int. Cl. B60L 58/10; G07C 5/08; G07C 5/00; G01R 31/392; G01R 31/367

(52) U.S. Cl. CPC B60L 58/10; G07C 5/0808; G01R 31/367; G01R 31/392; G07C 5/008

(57) ABSTRACT

A battery state determining system includes an in-vehicle device and a server. The in-vehicle device includes: an acquisition unit acquiring physical quantity data representing a physical quantity relating to a state of a battery mounted in a vehicle; a determination unit executing a determination process of determining whether or not the physical quantity represented by the physical quantity data satisfies a predetermined condition; and a transmission unit transmitting the physical quantity data to the server in a case in which it is determined that the physical quantity represented by the physical quantity data satisfies the predetermined condition in the determination process. The server includes: a reception unit receiving the physical quantity data from the in-vehicle device; and a diagnosis unit executing a diagnosis process of diagnosing an abnormality of the battery based on the physical quantity data and generating diagnosis result data representing a result of the diagnosis process.

### CROSS-REFERENCE TO RELATED APPLICATION

Priority is claimed on Japanese Patent Application No. 2019-097060, filed on May 23, 2019, the contents of which are incorporated herein by reference.

### BACKGROUND

### Field of the Invention

The present invention relates to a battery state determining system, an in-vehicle device, a server, a battery state determining method, and a program.

### Background

In recent years, the number of cases in which used batteries are mounted in electric vehicles (EVs), hybrid vehicles (HVs), and the like has increased. For this reason, technologies for determining battery states have become more important.

As one example of such technologies, in Japanese Unexamined Patent Application, First Publication No. 2013-092052, a battery abnormality detecting device including a detection means, a setting means, and an abnormality determining means has been disclosed. The detection means detects a voltage of a battery. The setting means acquires the voltage detected by the detection means within a predetermined period before a vehicle starts to travel after an operation of bringing an internal combustion engine into a startable state and sets an abnormality determination value on the basis of the acquired voltage. In a case in which the voltage detected by the detection means when the vehicle is traveling is lower than an abnormality determination value, the abnormality determining means determines that an abnormality has occurred.

### SUMMARY

However, the battery abnormality detecting device described above is a device that detects a voltage of the battery and detects an abnormality of the battery using an abnormality determination value set on the basis of the voltage but is not a device that recognizes a battery state using a physical quantity other than a voltage. For this reason, the battery abnormality detecting device cannot accurately recognize a battery state before an abnormality of the battery is diagnosed, and thus, the abnormality of the battery may not be accurately diagnosed.

An object of an aspect of the present invention is to provide a battery state determining system, an in-vehicle device, a server, a battery state determining method, and a program capable of recognizing a battery state more accurately.

According to a first aspect of the present invention, a battery state determining system is provided including an in-vehicle device and a server, the in-vehicle device including: an acquisition unit acquiring physical quantity data representing a physical quantity relating to a state of a battery mounted in a vehicle; a determination unit executing a determination process of determining whether or not the physical quantity represented by the physical quantity data satisfies a predetermined condition; and a transmission unit transmitting the physical quantity data to the server in a case in which it is determined that the physical quantity represented by the physical quantity data satisfies the predetermined condition in the determination process, and the server including: a reception unit receiving the physical quantity data from the in-vehicle device; and a diagnosis unit executing a diagnosis process of diagnosing an abnormality of the battery based on the physical quantity data and generating diagnosis result data representing a result of the diagnosis process.

According to a second aspect of the present invention, in the battery state determining system according to the first aspect described above, the acquisition unit may acquire at least first physical quantity time data representing change in a first physical quantity with respect to time and second physical quantity time data representing change in a second physical quantity, which is a physical quantity of a kind different from that of the first physical quantity, with respect to time as the physical quantity data, the determination unit may determine whether or not a trace of a point representing an operating history of the battery inside a battery state determination space defined by at least a first axis representing the first physical quantity and a second axis representing the second physical quantity satisfies the predetermined condition in the determination process, and the transmission unit may transmit operating history data representing the operating history of the battery to the server in a case in which it is determined that the trace of the point satisfies the predetermined condition in the determination process.

According to a third aspect of the present invention, an in-vehicle device is provided including: an acquisition unit acquiring physical quantity data representing a physical quantity relating to a state of a battery mounted in a vehicle; a determination unit executing a determination process of determining whether or not the physical quantity represented by the physical quantity data satisfies a predetermined condition; and a transmission unit transmitting the physical quantity data to a server executing a diagnosis process of diagnosing an abnormality of the battery based on the physical quantity data in a case in which it is determined that the physical quantity represented by the physical quantity data satisfies the predetermined condition in the determination process.

According to a fourth aspect of the present invention, a server communicating with an in-vehicle device is provided, the server including: a reception unit receiving physical quantity data that represents a physical quantity relating to a state of a battery mounted in a vehicle and is transmitted by the in-vehicle device in a case in which it is determined that the physical quantity satisfies a predetermined condition; and a diagnosis unit executing a diagnosis process of diagnosing an abnormality of the battery based on the physical quantity data and generating diagnosis result data representing a result of the diagnosis process.

According to a fifth aspect of the present invention, a battery state determining method is provided including: acquiring physical quantity data representing a physical quantity relating to a state of a battery mounted in a vehicle by using an in-vehicle device; executing a determination process of determining whether or not the physical quantity represented by the physical quantity data satisfies a predetermined condition by using the in-vehicle device; transmitting the physical quantity data to a server in a case in which it is determined that the physical quantity represented by the physical quantity data satisfies the predetermined condition in the determination process by using the in-vehicle device; receiving the physical quantity data from the in-vehicle device by using the server; and executing a diagnosis process of diagnosing an abnormality of the battery based on the physical quantity data and generating diagnosis result data representing a result of the diagnosis process by using the server.

According to a sixth aspect of the present invention, a computer-readable non-transitory recording medium is provided including a program causing a computer of an in-vehicle device to perform: acquiring physical quantity data representing a physical quantity relating to a state of a battery mounted in a vehicle; executing a determination process of determining whether or not the physical quantity represented by the physical quantity data satisfies a predetermined condition; and transmitting the physical quantity data to a server executing a diagnosis process of diagnosing an abnormality of the battery based on the physical quantity data in a case in which it is determined that the physical quantity represented by the physical quantity data satisfies the predetermined condition in the determination process.

According to a seventh aspect of the present invention, a computer-readable non-transitory recording medium is provided including a program causing a computer of a server communicating with an in-vehicle device to perform: receiving physical quantity data that represents a physical quantity relating to a state of a battery and is transmitted by the in-vehicle device in a case in which it is determined that the physical quantity satisfies a predetermined condition; and executing a diagnosis process of diagnosing an abnormality of the battery based on the physical quantity data and generating diagnosis result data representing a result of the diagnosis process.

According to the first, second, third, fifth, and sixth aspects described above, by determining whether or not a physical quantity relating to a battery state satisfies a predetermined condition, the battery state can be recognized more accurately before an abnormality of the battery is diagnosed.

According to the second aspect described above, by determining whether or not an operating history of a battery satisfies a predetermined condition, the battery state including a past operating state can be recognized more accurately before an abnormality of the battery is diagnosed.

According to the fourth and seventh aspects described above, in a case in which it is determined that a physical quantity relating to the battery state satisfies a predetermined condition, physical quantity data is received, and an abnormality of the battery is diagnosed. Therefore, a load for executing a diagnosis process for a battery for which a diagnosis process does not need to be performed can be omitted.

### BRIEF DESCRIPTION OF THE DRAWINGS

FIG. 1 is a diagram illustrating an example of a battery state determining system according to an embodiment.

FIG. 2 is a diagram illustrating an example of a vehicle according to the embodiment.

FIG. 3 is a diagram illustrating an example of a battery state determination space according to the embodiment.

FIG. 4 is a sequence diagram illustrating an example of a process executed by a battery state determining system according to the embodiment.

### DESCRIPTION OF EMBODIMENTS

Hereinafter, a battery state determining system, an in-vehicle device, and a server according to an embodiment of the present invention will be described with reference to the drawings.

### Embodiment

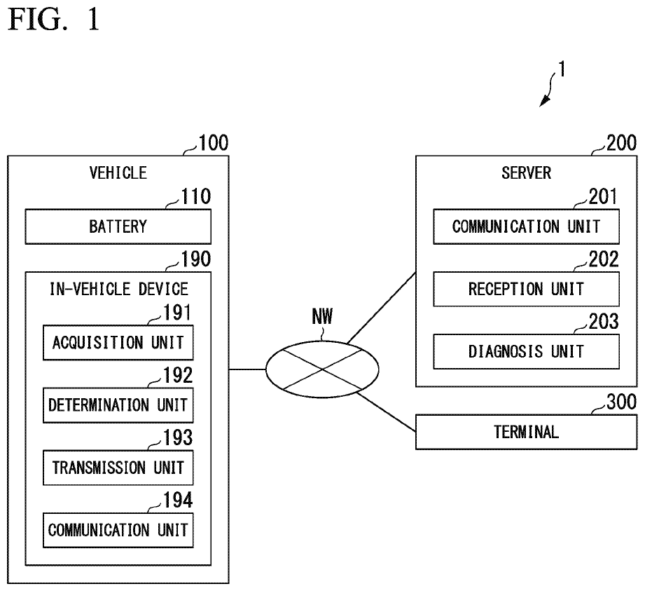

A battery state determining system, an in-vehicle device, and a server according to an embodiment will be described with reference to FIGS. 1 to 3. FIG. 1 is a diagram illustrating an example of a battery state determining system according to an embodiment. As illustrated in FIG. 1, the battery state determining system 1 includes a vehicle 100, a server 200, and a terminal 300. All the vehicle 100, the server 200, and the terminal 300 are connected to a network NW such that they are able to communicate with other devices. The network NW, for example, includes a wide area network (WAN), a local area network (LAN), and the Internet.

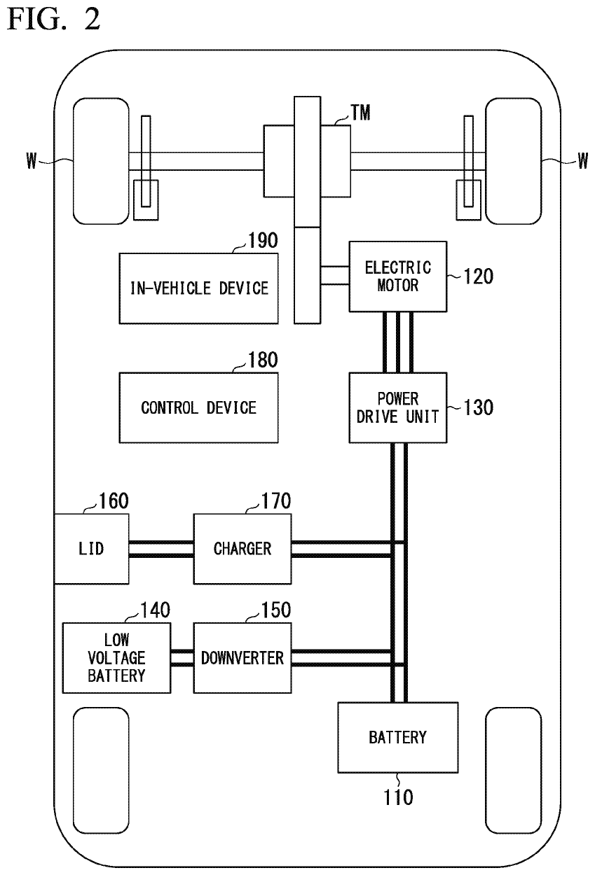

FIG. 2 is a diagram illustrating an example of the configuration of a vehicle according to an embodiment. As illustrated in FIGS. 1 and 2, the vehicle 100 includes a battery 110, an electric motor 120, a power drive unit (PDU) 130, a low voltage battery 140, a downverter 150, a lid 160, a charger 170, a control device 180, and an in-vehicle device 190.

The vehicle 100 is a vehicle in which a secondary battery is mounted and, for example, is an electric vehicle (EV) of a plugin type. In this case, the vehicle 100 is connected to an external feed device using a charging cable and can charge the battery 110 with electric power supplied from the external feed device.

The battery 110, for example, is a secondary battery such as a lithium ion battery. The battery 110 can transfer DC power to the power drive unit 130 and the downverter 150. In addition, the battery 110 is charged by DC power supplied from the charger 170.

The electric motor 120 is a motor, for example, a three-phase DC brushless motor. The electric motor 120 converts electrical energy supplied from the battery 110 as DC power into mechanical energy. This mechanical energy is transmitted to drive wheels W through a transmission TM and rotates the drive wheels W. In addition, for example, in a case in which mechanical energy is transmitted from the drive wheels W in accordance with braking of the vehicle 100, the electric motor 120 generates a regenerative braking force by operating as a power generator and converts kinetic energy of the vehicle 100 into electrical energy. This electrical energy is AC power. This AC power is converted into DC power by the power drive unit 130 and is accumulated in the battery 110.

The power drive unit 130 includes an inverter that performs pulse width modulation (PWM). The power drive unit 130 converts DC power supplied from the battery 110 into AC power and supplies the converted AC power to the electric motor 120. In addition, in a case in which the electric motor 120 operates as a power generator, the power drive unit 130 converts AC power supplied from the electric motor 120 into DC power and supplies the converted DC power to the battery 110.

The low voltage battery 140 is a battery that supplies power to various auxiliary machines. An inter-terminal voltage of the low voltage battery 140, for example, is 12 V.

The downverter 150 charges the low voltage battery 140 by lowering at least one of an inter-terminal voltage of the battery 110, an inter-terminal voltage of the power drive unit 130, and an inter-terminal voltage of the low voltage battery 140 to a predetermined voltage. In addition, for example, in a case in which a state of charge (SOC) of the battery 110 becomes low, the downverter 150 charges the battery 110 by raising the inter-terminal voltage of the low voltage battery 140.

The lid 160 is a terminal that is connected to the charger 170. In a case in which charging of the battery 110 is executed, the lid 160 is connected to the charging cable described above. This charging cable includes a charging circuit interrupt device (CCID). The charging circuit interrupt device executes detection of a connection state between the charging cable and the vehicle 100 and electric cutoff between an external feed device and the vehicle 100 at the time of occurrence of an overcurrent or an electric leakage.

The charger 170 converts DC power supplied from the external feed device through the charging cable into DC power using the inverter and supplies the converted DC power to the battery 110. In the case of being connected to the external feed device using the charging cable, the charger 170 can operate owing to the supply of power from the external feed device even when the power of the vehicle 100 is off. The charger 170 is controlled to operate or not in accordance with a control pilot signal (CPI) output from the charging circuit interrupt device described above.

By controlling the operation of the power drive unit 130, the control device 180 controls generation of mechanical energy and electrical energy using the electric motor 120. In addition, by controlling the operation of the downverter 150, the control device 180 controls charging of the low voltage battery 140 and the charging of the battery 110. In this case, the control device 180 may control the charging of the low voltage battery 140 on the basis of a charging rate of the low voltage battery 140 and may control the charging of the battery 110 on the basis of a charging rate of the battery 110.

As illustrated in FIG. 1, the in-vehicle device 190 includes an acquisition unit 191, a determination unit 192, a transmission unit 193, and a communication unit 194. As illustrated in FIG. 1, the server 200 includes a communication unit 201, a reception unit 202, and a diagnosis unit 203. Each of the acquisition unit 191, the determination unit 192, the transmission unit 193, the communication unit 194, the communication unit 201, the reception unit 202, and the diagnosis unit 203 is, for example, realized by a hardware processor such as a central processing unit (CPU) executing a program or software.

Some or all of the functions included in the in-vehicle device 190 or the server 200 may be realized by hardware including a circuitry such as a large scale integration (LSI), an application specific integrated circuit (ASIC), a field-programmable gate array (FPGA), or a graphics processing unit (GPU) or may be realized by software and hardware in cooperation. The program may be stored in advance in a storage device including a non-transitory storage medium such as a hard disk drive (HDD) or a flash memory or may be stored in a non-transitory storage medium that can be loaded or unloaded such as a DVD or a CD-ROM and be installed by loading the storage medium into a drive device.

The acquisition unit 191 acquires physical quantity data representing physical quantities relating to a state of the battery 110. The physical quantities described here, for example, are a charging rate, an open circuit voltage (OCV), an internal resistance, and a capacity of the battery 110.

In addition, it is preferable that the acquisition unit 191 should acquire at least first physical quantity time data and second physical quantity time data as physical quantity data. The first physical quantity time data is data that represents change in a first physical quantity, for example, an open circuit voltage of the battery 110 with respect to time. The second physical quantity time data is data that represents change in a second physical quantity, which is physical quantity data of a kind different from that of the first physical quantity, for example, a capacity of the battery 110 with respect to time. In the following description, a case in which the acquisition unit 191 acquires data representing change in the open circuit voltage with respect to time as first physical quantity time data, acquires data representing change in the capacity with respect to time as second physical quantity time data, and acquires data representing change in the internal resistance with respect to time as third physical quantity time data will be described as an example.

The determination unit 192 executes a determination process of determining whether or not a physical quantity represented by the physical quantity data satisfies a predetermined condition. The predetermined condition described here is a condition derived from a value of a physical quantity of a battery, which is normally operating, at each time and, for example, is a range of the internal resistance represented by a battery that is normally operating. In addition, the predetermined condition described here may be a condition derived through a simulation. The determination unit 192 executes a determination process in order to be described below.

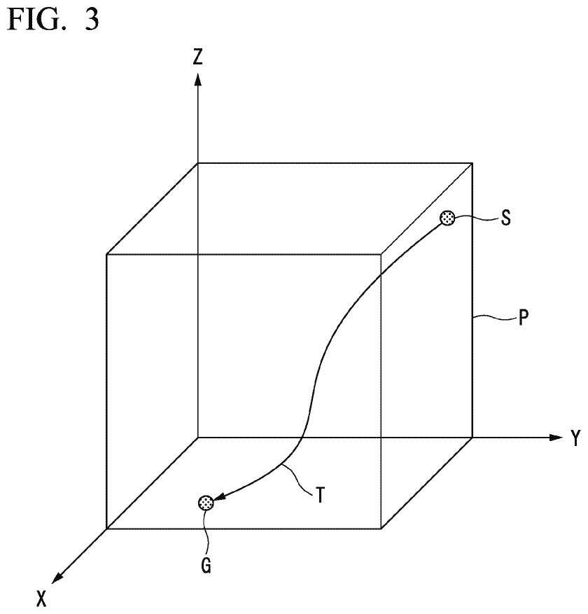

First, the determination unit 192 generates a battery state determination space on the basis of physical quantity data acquired by the acquisition unit 191. FIG. 3 is a diagram illustrating an example of a battery state determination space according to an embodiment. For example, the determination unit 192 generates the battery state determination space P illustrated in FIG. 3 on the basis of the first physical quantity time data, the second physical quantity time data, and the third physical quantity time data described above that have been acquired by the acquisition unit 191.

The battery state determination space P is a three-dimensional linear space defined by a first axis X representing an open circuit voltage that is one example of the first physical quantity, a second axis Y representing a capacity that is one example of the second physical quantity, and a third axis Z representing an internal resistance that is one example of the third physical quantity. The first axis X, the second axis Y, and the third axis Z are determined by the determination unit 192 in accordance with kinds of physical quantities represented by the physical quantity data acquired by the acquisition unit 191. Thus, in this case, the first axis X represents the open circuit voltage of the battery 110, the second axis Y represents the capacity of the battery 110, and the third axis Z represents the internal resistance of the battery 110.

Next, the determination unit 192 visualizes physical quantities represented by the first physical quantity time data, the second physical quantity time data, and the third physical quantity time data described above inside the battery state determination space P. For example, as illustrated in FIG. 3, the determination unit 192 visualizes a trace T having a point S as its start point and a point G as its end point inside the battery state determination space P.

The point S represents an open circuit voltage, a capacity, and an internal resistance at a time point at which the battery 110 starts an operation. In other words, an X coordinate of the point S represents an open circuit voltage of the battery 110 at the time point. Similarly, a Y coordinate of the point S represents a capacity of the battery 110 at the time point. In addition, a Z coordinate of the point S represents an internal resistance of the battery 110 at the time point.

The point G represents an open circuit voltage, a capacity, and an internal resistance at a time point at which the battery 110 ends an operation. In other words, an X coordinate of the point G represents an open circuit voltage of the battery 110 at the time point. Similarly, a Y coordinate of the point G represents a capacity of the battery 110 at the time point. In addition, a Z coordinate of the point G represents an internal resistance of the battery 110 at the time point.

The trace T is a line acquired by joining points representing an open circuit voltage, a capacity, and an internal resistance at each time in a period until an operation ends after the battery 110 starts the operation. The trace T represents physical quantities represented by the first physical quantity time data, the second physical quantity time data, and the third physical quantity time data. The points forming the trace T represent an operating history of the battery 110.

The determination unit 192 executes a determination process of determining whether or not a trace of points representing an operating history of the battery inside a battery state determination space that is defined by at least the first axis representing the first physical quantity and the second axis representing the second physical quantity satisfies a predetermined condition. For example, the determination unit 192 determines whether or not at least part of the trace T illustrated in FIG. 3 is included in a first area inside the battery state determination space P. The first area described here is a set of points representing physical quantities suggesting a possibility of an abnormality of the battery 110. Instead of this, the determination unit 192 may determine whether or not at least part of the trace T deviates from a second area inside the battery state determination space P. The second area is an area that is traced by the trace T in a case in which the battery 110 is normal.

In a case in which it is determined that physical quantities represented by the physical quantity data satisfy a predetermined condition in the determination process, the transmission unit 193 transmits physical quantity data to the server 200 using the communication unit 194. For example, in a case in which it is determined that at least part of the trace T is included in a predetermined area in the determination process, the transmission unit 193 transmits operating history data representing an operating history of the battery 110 to the server 200 using the communication unit 194. Here, the operating history data is one example of the physical quantity data.

The communication unit 194 transmits physical quantity data to the server 200 through the network NW illustrated in FIG. 1 under the control of the transmission unit 193.

The communication unit 201 receives physical quantity data from the in-vehicle device 190 through the network NW illustrated in FIG. 1 under the control of the reception unit 202.

The reception unit 202 receives physical quantity data received by the communication unit 201.

The diagnosis unit 203 executes a diagnosis process of diagnosing an abnormality of the battery on the basis of physical quantity data and generates a diagnosis result data representing a result of the diagnosis process. The diagnosis result data is transmitted to the terminal 300 through the network NW illustrated in FIG. 1. The terminal 300, for example, displays a result of the diagnosis process represented by the diagnosis result data on a display.

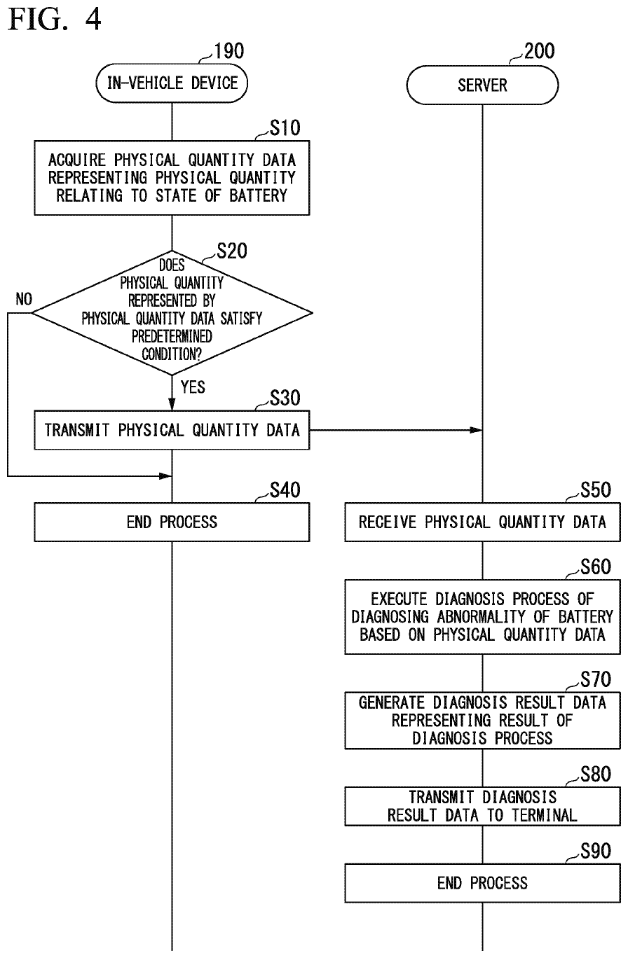

Next, a process executed by the battery state determining system 1 according to an embodiment will be described with reference to FIG. 4. FIG. 4 is a sequence diagram illustrating an example of a process executed by a battery state determining system according to an embodiment.

The acquisition unit 191 acquires physical quantity data representing a physical quantity relating to the state of the battery (Step S10).

The determination unit 192 determines whether or not a physical quantity represented by the physical quantity data satisfies a predetermined condition (Step S20). In a case in which it is determined that the physical quantity represented by the physical quantity data satisfies the predetermined condition (Yes in Step S20), the determination unit 192 causes the process to proceed to Step S30. On the other hand, in a case in which it is determined that the physical quantity represented by the physical quantity data does not satisfy the predetermined condition (No in Step S20), the determination unit 192 causes the process to proceed to Step S40.

The transmission unit 193 transmits the physical quantity data (Step S30). More specifically, the transmission unit 193 transmits physical quantity data to the server 200 using the communication unit 194.

The in-vehicle device 190 ends the process (Step S40).

The reception unit 202 receives the physical quantity data (Step S50). More specifically, the reception unit 202 receives the physical quantity data from the server 200 using the communication unit 201.

The diagnosis unit 203 executes a diagnosis process of diagnosing an abnormality of the battery 110 on the basis of the physical quantity data (Step S60).

The diagnosis unit 203 generates diagnosis result data that represents a result of the diagnosis process (Step S70).

The server 200 transmits the diagnosis result data to the terminal 300 (Step S80).

The server 200 ends the process (Step S90).

As above, the battery state determining system 1 according to an embodiment has been described. The battery state determining system 1 includes the in-vehicle device 190 that transmits physical quantity data to the server in a case in which it is determined that a physical quantity represented by the physical quantity data representing the physical quantity relating to the state of the battery 110 satisfies a predetermined condition. In accordance with this, by determining whether or not a physical quantity relating to the state of the battery 110 satisfies the predetermined condition, the battery state determining system 1 can recognize the state of the battery 110 more accurately before an abnormality of the battery 110 is diagnosed.

In addition, in a case in which it is determined that a trace of points representing an operating history of the battery 110 inside a battery state determination space defined by at least the first axis representing the first physical quantity and the second axis representing the second physical quantity satisfies a predetermined condition, the battery state determining system 1 transmits operating history data representing the operating history of the battery 110 to the server 200. In accordance with this, the battery state determining system 1 can recognize the state of the battery including the operating state in the past more accurately before an abnormality of the battery is diagnosed.

Furthermore, the battery state determining system 1 includes the server 200 that executes a diagnosis process of receiving physical quantity data and diagnosing an abnormality of the battery 110 in a case in which it is determined that a physical quantity relating to the state of the battery 110 satisfies a predetermined condition. In accordance with this, the battery state determining system 1 can omit a load for executing a diagnosis process for a battery 110 for which the diagnosis process does not need to be executed.

Although a case in which the vehicle 100 is an electric vehicle has been described as an example in the embodiment described above, the vehicle 100 is not limited thereto. Thus, the vehicle 100 may be a hybrid vehicle (HV).

In addition, although the case of the three-dimensional battery state determination space has been described as an example in the embodiment described above, the battery state determination space is not limited thereto. Thus, the dimensions of the battery state determination space may be one dimension, two dimensions, or four or more dimensions.

In addition, although a case in which the in-vehicle device 190 executes the determination process on the basis of the trace T inside the battery state determination space P defined by the first axis X, the second axis Y, and the third axis Z has been described as an example in the embodiment described above, the determination process is not limited thereto. Thus, the in-vehicle device 190 may execute the determination process on the basis of not the operating history but a physical quantity at a predetermined time.

In addition, although a case in which the in-vehicle device 190 directly uses a physical quantity represented by the physical quantity data for the determination process has been described as an example in the embodiment described above, the determination process is not limited thereto. For example, the in-vehicle device 190 may execute a determination process on the basis of a feature quantity extracted from a physical quantity represented by the physical quantity data.

As above, although a form used for performing the present invention has been described using the embodiment, the present invention is not limited to such an embodiment at all, and various modifications and substitutions within a range not departing from the concept of the present invention may be applied.

What is claimed is:

1. A battery state determining system comprising:
an in-vehicle device; and
a server,
wherein the in-vehicle device includes:
an acquisition unit acquiring physical quantity data representing a physical quantity relating to a state of a battery mounted in a vehicle;
a determination unit executing a determination process of determining whether or not the physical quantity represented by the physical quantity data satisfies a predetermined condition; and
a transmission unit transmitting the physical quantity data to the server in a case in which it is determined that the physical quantity represented by the physical quantity data satisfies the predetermined condition in the determination process, and
wherein the server includes:
a reception unit receiving the physical quantity data from the in-vehicle device; and
a diagnosis unit executing a diagnosis process of diagnosing an abnormality of the battery based on the physical quantity data and generating diagnosis result data representing a result of the diagnosis process.

2. The battery state determining system according to claim 1,
wherein the acquisition unit acquires at least first physical quantity time data representing change in a first physical quantity with respect to time and second physical quantity time data representing change in a second physical quantity, which is a physical quantity of a kind different from that of the first physical quantity, with respect to time as the physical quantity data,
wherein the determination unit determines whether or not a trace of a point representing an operating history of the battery inside a battery state determination space defined by at least a first axis representing the first physical quantity and a second axis representing the second physical quantity satisfies the predetermined condition in the determination process, and
wherein the transmission unit transmits operating history data representing the operating history of the battery to the server in a case in which it is determined that the trace of the point satisfies the predetermined condition in the determination process.

3. An in-vehicle device comprising:
an acquisition unit acquiring physical quantity data representing a physical quantity relating to a state of a battery mounted in a vehicle;
a determination unit executing a determination process of determining whether or not the physical quantity represented by the physical quantity data satisfies a predetermined condition; and
a transmission unit transmitting the physical quantity data to a server executing a diagnosis process of diagnosing an abnormality of the battery based on the physical quantity data in a case in which it is determined that the physical quantity represented by the physical quantity data satisfies the predetermined condition in the determination process.

4. A server communicating with an in-vehicle device, the server comprising:
a reception unit receiving physical quantity data that represents a physical quantity relating to a state of a battery mounted in a vehicle and is transmitted by the in-vehicle device in a case in which it is determined that the physical quantity satisfies a predetermined condition; and
a diagnosis unit executing a diagnosis process of diagnosing an abnormality of the battery based on the physical quantity data and generating diagnosis result data representing a result of the diagnosis process.

5. A battery state determining method comprising:
acquiring physical quantity data representing a physical quantity relating to a state of a battery mounted in a vehicle by using an in-vehicle device;
executing a determination process of determining whether or not the physical quantity represented by the physical quantity data satisfies a predetermined condition by using the in-vehicle device;
transmitting the physical quantity data to a server in a case in which it is determined that the physical quantity represented by the physical quantity data satisfies the predetermined condition in the determination process by using the in-vehicle device;
receiving the physical quantity data from the in-vehicle device by using the server; and
executing a diagnosis process of diagnosing an abnormality of the battery based on the physical quantity data and generating diagnosis result data representing a result of the diagnosis process by using the server.

6. A computer-readable non-transitory recording medium including a program causing a computer of an in-vehicle device to perform:
acquiring physical quantity data representing a physical quantity relating to a state of a battery mounted in a vehicle;
executing a determination process of determining whether or not the physical quantity represented by the physical quantity data satisfies a predetermined condition; and
transmitting the physical quantity data to a server executing a diagnosis process of diagnosing an abnormality of the battery based on the physical quantity data in a case in which it is determined that the physical quantity represented by the physical quantity data satisfies the predetermined condition in the determination process.

7. A computer-readable non-transitory recording medium including a program causing a computer of a server communicating with an in-vehicle device to perform:
receiving physical quantity data that represents a physical quantity relating to a state of a battery and is transmitted by the in-vehicle device in a case in which it is determined that the physical quantity satisfies a predetermined condition; and
executing a diagnosis process of diagnosing an abnormality of the battery based on the physical quantity data and generating diagnosis result data representing a result of the diagnosis process.
